(19) United States
(12) Patent Application Publication
(10) Pub. No.: US 2005/0251714 A1
(43) Pub. Date: Nov. 10, 2005

(54) Test apparatus for semiconductor devices built-in self-test function

(75) Inventor: Yasumasa Nishimura, Tokyo (JP)

Correspondence Address: MCDERMOTT WILL & EMERY LLP, 600 13TH STREET, N.W., WASHINGTON, DC, 20005-3096, US

(73) Assignee: Renasas Technology Corp., Tokyo (JP)

(21) Appl. No.: 11/183,881

(22) Filed: Jul. 19, 2005

Related U.S. Application Data
(62) Division of application No. 10/098,442, filed on Mar. 18, 2002.

(30) Foreign Application Priority Data
Jul. 12, 2001 (JP) 2001-211662

(51) Int. Cl. G01R 31/28

(52) U.S. Cl. 714/733

(57) ABSTRACT

A test apparatus for semiconductor devices comprises a self-test circuit carried on the semiconductor device and for test the semiconductor device. A tester supplies data signals, clock signals, and expected value data to the self-test circuit. A comparing and judging circuit compares the result of test with the expected-value data to judge the quality of the semiconductor device. A non-volatile memory cell stores the results of judgment.

### BACKGROUND OF THE INVENTION

1. Field of the Invention

The present invention relates to an apparatus and a method for test of semiconductor devices, particularly, test of semiconductor devices having built-in self-test (hereafter abbreviated as BIST) function embedded therein, or full-wafer test of a plurality of such semiconductor devices carried on a semiconductor wafer.

2. Description of the Background Art

FIG. 14 is a block diagram showing the conventional test for semiconductor devices through use of a tester. In FIG. 14, the reference numeral 1 denotes a main body of the tester, which generates test pattern signals required as the test condition of semiconductor devices.

The reference numeral 2 denotes a DC measurement unit for measuring a DC current, and transmits or receive signals to or from a device under test (hereafter abbreviated as DUT) corresponding to the control signals supplied from the main body of the tester 1 through a cable 3. The reference numeral 5 denotes a test head connected to the main body of the tester 1 through a cable 6, and transmits or receive signals to or from the DUT 4 corresponding to the control signals supplied from the main body of the tester 1. In other words, when the DUT 4 is tested, test signals are generated from a tester driver 8 of a pin electronics card 7 accommodated in the test head 5, and the test signals are supplied to the DUT 4.

The comparator 9 in the pin electronics card 7 receives responding signals from the DUT 4, and compares the signals with an expected value 10 to determine if the DUT 4 operates as designed.

In recent years, as the scale of semiconductor devices has enlarged and become complicated, the difficulty of the test of semiconductor devices has increased from year to year. In order to reduce the burden of semiconductor test apparatuses, and to facilitate the test, semiconductor devices with BIST function embedded therein have been developed. Due to the development of the BIST technology, the function test, conventionally conducted using semiconductor test apparatuses as shown in the above-described FIG. 14, has become possible by semiconductor devices themselves.

FIG. 15 is a schematic diagram showing a conventional test method of a DUT having BIST.

In this method, since the DUT 4A conducts self-test by supplying a power source (not shown), a ground potential (GND), and clock signals to the DUT 4A with BIST function embedded therein from the test head 5 corresponding to the control signals supplied from the main body of the tester 1 through the cable 6, and feeds the result of the test back to the test head 5, the quality of the DUT 4A can be known easily.

Since the constitution of the BIST is well known from a number of reports, the description will be omitted; however, by incorporating a BIST in every semiconductor device on a wafer, all the semiconductor devices on the wafer can be tested in a full-wafer manner.

Since the conventional test apparatus is constituted as described above, and has specifications to deal with the function test of DUT, one test apparatus costs as high as several hundred million yen.

Also, since the probing needle that can test wafers in a full-wafer manner is fabricated to meet each model, and has different constitutions for different models, it cannot be used for different DUT, and costs as high as several ten million yen. Furthermore, in the case of a complicated large-scale semiconductor device having the above-described BIST function embedded therein, as shown in FIG. 16, the area of the BIST functional unit 4C is excessively added to the area of the device functional unit 4B, which is an operating portion, resulting in increase in the manufacturing costs of semiconductor devices.

### SUMMARY OF THE INVENTION

The present invention has been conceived to solve the previously-mentioned problems and a general object of the present invention is to provide a novel and useful test apparatus for semiconductor devices.

The above object of the present invention is attained by a following test apparatus for semiconductor devices.

According to a first aspect of the present invention, the test apparatus for semiconductor devices comprises a self-test circuit carried on the semiconductor device and for test the semiconductor device. A tester supplies data signals, clock signals, and expected value data to the self-test circuit. A comparing and judging circuit compares the result of test with the expected-value data to judge the quality of the semiconductor device. A non-volatile memory cell stores the results of judgment. Accordingly, the test apparatus can conduct tests efficiently and easily

According to a second aspect of the present invention, the test apparatus for semiconductor devices comprises a self-test circuit carried on the semiconductor device and for test the semiconductor device. A tester supplies data signals, clock signals, and expected value data to the self-test circuit. A comparing and judging circuit compares the result of test with the expected-value data to judge the quality of the semiconductor device. A fuse device melts a fuse corresponding to the result of judgment and for storing the result of judgment by changing the output potential. Accordingly, the test apparatus can easily check the test result.

According to a third aspect of the present invention, the test apparatus for semiconductor devices, the semiconductor devices on a wafer being tested in a full-wafer manner, each semiconductor device carrying a self-test circuit, comprises a probing needle device. The probing needle device has a mother board including POGO contacts for receiving signals from the tester; and a daughter board connected to the mother board and including a plurality of needles for electrically connecting to each semiconductor device on the wafer. Wherein, several needles are used for one semiconductor device. Accordingly, the constitution of the probing needle device becomes simplified.

Other objects and further features of the present invention will be apparent from the following detailed description when read in conjunction with the accompanying drawings.

### BRIEF DESCRIPTION OF THE DRAWINGS

FIG. 1 is a block diagram showing the constitution and test method of First Embodiment;

FIG. 2 is a block diagram showing the constitution of the major part of Second Embodiment;

FIG. 3 is a block diagram showing the constitution of a low-cost tester constituting the major part of Third Embodiment;

FIG. 4 is a block diagram showing one constitution of Third Embodiment;

FIG. 5 is a block diagram showing another constitution of Third Embodiment;

FIG. 6A is a schematic diagram showing the constitution of the probing needle device;

FIG. 6B is a schematic diagram showing a wafer to be tested;

FIG. 7 is a schematic diagram showing one constitution of Fifth Embodiment;

FIG. 8 is a schematic diagram showing another constitution of Fifth Embodiment;

FIG. 9 is a flow chart that shows a test method according to Sixth Embodiment;

FIG. 10 is a flow chart for discriminating between good and defective DUT;

FIG. 11 is a block diagram showing the constitution of Seventh Embodiment;

FIG. 12 shows a constitution of the handy pin electronics card 80 shown in FIG. 11;

FIG. 13 is a schematic diagram showing the constitution and a testing method of Eighth Embodiment;

FIG. 14 is a block diagram showing the conventional test for semiconductor devices that uses a tester;

FIG. 15 is a schematic diagram showing a conventional test method of a DUT having BIST; and

FIG. 16 is a diagram showing the relation that the area of BIST function unit is excessively added to the area of the device functional unit.

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefore may be omitted.

### First Embodiment

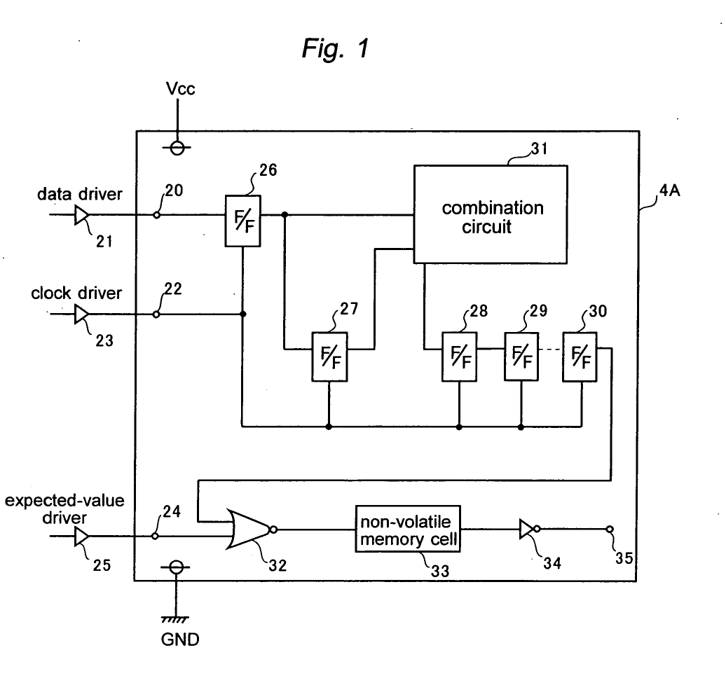

First Embodiment of the present invention will be described below referring to FIG. 1.

FIG. 1 is a block diagram showing the constitution and test method of First Embodiment. In FIG. 1, the reference numeral 4A denotes a DUT with BIST function embedded therein, and the scan-test design is applied to the design thereof. Reference symbol Vcc denotes a source voltage supplied from the power source for devices of an external tester (not shown), and GND denotes a ground potential supplied from the external tester (not shown); the reference numeral 20 denotes a data input terminal, to which data for the test is supplied from the data driver 21 carried by the external tester (not shown). The reference numeral 22 denotes a clock signal input terminal, to which clock signals are supplied from a clock driver 23 carried by the above-descried tester. The reference numeral 24 denotes an expected-value data input terminal, to which expected-value data required to judge the test result is supplied from the expected-value driver 25 carried by the above-descried tester.

The reference numerals 26 to 30 denote flip-flops in the DUT of the scan-test design, which is controlled by clock signals supplied from the clock-signal input terminal 22, and data for the test supplied from the data input terminal 20 is set in each flip-flop.

The reference numeral 31 denotes a combination circuit in the DUT, which is tested based on the data for the test set in each of flip-flops 26 to 30, and the test result is incorporated in each flip-flop.

The reference numeral 32 denotes a comparator circuit that takes exclusive OR, which compares the expected value supplied from the expected-value input terminal 24 with the test result incorporated in each of flip-flops 26 to 30, and judges the quality of the DUT.

In this example, “0” is outputted when the DUT passed the test, and “1” is outputted when the DUT did not pass the test. The reference numeral 33 denotes a non-volatile memory cell to store the result of judgments, which is constituted by a well-known flash memory cell or EEPROM cell.

The reference numeral 34 denotes an inverter for inverting the output of the non-volatile memory cell 33, and “1” is outputted to the judgment output terminal 35 when the DUT passed the test, and “0” is outputted to the terminal 35 when the DUT did not pass the test.

In First Embodiment, since the result of judgment is stored in the non-volatile memory cell 33, the result of the test is retained even if the power is turned off after the completion of the test.

Therefore, the quality of a device can be known easily by reading the information stored in the non-volatile memory cell 33 from the judgment output terminal 35.

### Second Embodiment

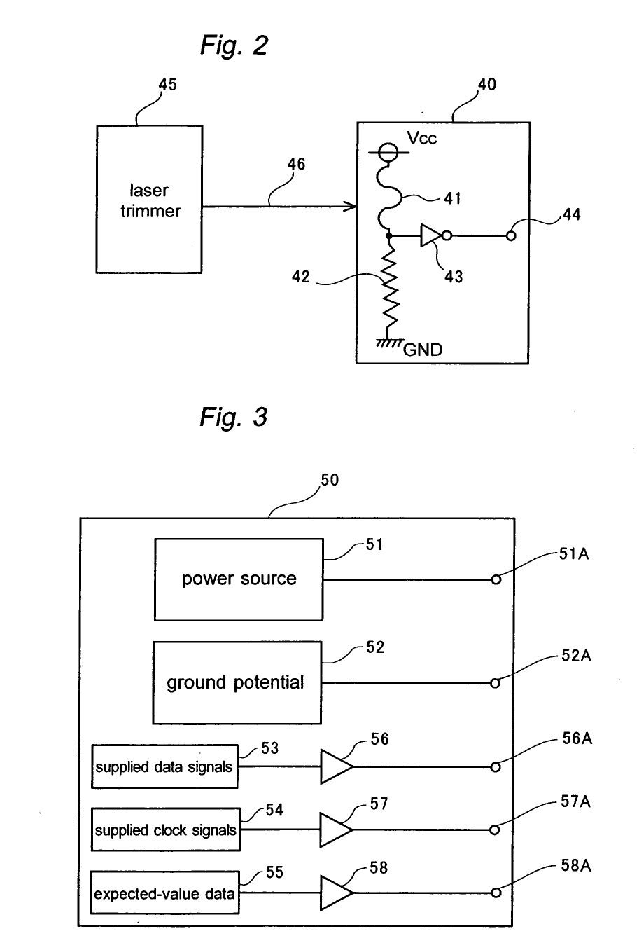

Next, Second Embodiment of the present invention will be described below referring to FIG. 2.

FIG. 2 is a block diagram showing the constitution of the major part of Second Embodiment, in which a fuse device is used in place of the non-volatile memory cell used in First Embodiment, and other constitution is the same as in First Embodiment.

In FIG. 2, the reference numeral 40 denotes a fuse device, the fuse device 40 having a fuse 41 and a high resistance 42 connected between the power source voltage Vcc and the ground potential GND, an inverter 43 connected to the fuse-side terminal of the high resistance 42, and a judgment output terminal 44 connected to the output side of the inverter 43. The reference numeral 45 denotes a laser trimmer, which operates when the comparator circuit 32 determines the DUT as a good product and radiates laser beams 46 to the fuse 41, and melts the fuse 41.

As a result, the input of the inverter 43 becomes “0” level, the data is inverted, and “1” is outputted to the judgment output terminal 44. That is, as in First Embodiment, when the DUT is good, “1” level is outputted, when the DUT is not good, “0” level is outputted, and the state is retained. Alternatively, the same effect is expected if the fuse is melted by an electrical signal (not shown) generated when the DUT is determined as a good product, instead of the melting of the fuse 41 by the laser beams 46.

### Third Embodiment

Next, Third Embodiment of the present invention will be described below referring to the drawings.

FIG. 3 is a block diagram showing the constitution of a low-cost tester constituting the major part of Third Embodiment. In FIG. 3, the reference numeral 50 denotes a low-cost tester, which has the constitution described below. The reference numeral 51 denotes a power source for a DUT, and 51A denotes the supply terminal for the power source 51, which supplies the voltage as the power source Vcc of FIG. 1. The reference numeral 52 denotes the ground potential for the DUT, and 52A denotes the supply terminal for the ground potential, which supplies the potential as the ground potential GND of FIG. 1. The reference numeral 53 denotes supplied data signals for the DUT, which is for generating minimum required supplied data signals corresponding to the DUT. The reference numeral 54 denotes supplied clock signals for the DUT, which generates prescribed clock signals. The reference numeral 55 denotes expected-value data, which are generated as the reference values for judging the quality of the DUT. The reference numerals 56 to 58 which receive supplied data signal 53, supplied clock signal 54 and expected-value data 55, respectively are handy drivers for generating pulse signals corresponding to each signal, which are supplied to the data input terminal 20, the clock-signal input signal 22, and the expected-value input terminal 24 through output terminals 56A to 58A of FIG. 1, respectively.

Since Third Embodiment is constituted as described above, and the signals supplied from the tester to the DUT are limited, the tester can be constituted at a low cost.

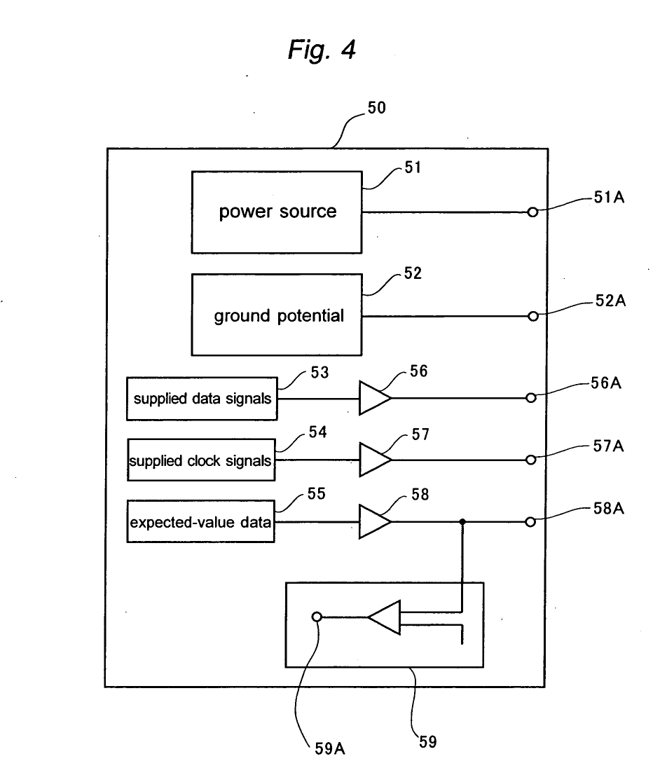

As FIG. 4 shows, if a handy comparator 59, which reads the test result from the monitor terminal (not shown) of the DUT, and compares the test result with the expected-value data, is connected to the handy driver 58 for impressing expected-value data, and the result of comparison is outputted from the output terminal 59A as the quality determination result of the DUT, the quality of the DUT can be easily determined.

Alternatively, the same effect can be expected if the handy comparator 59 is connected to the handy driver 56 of supplied data signals in place of the handy driver 58 for impressing expected-value data. In FIG. 4, the same of corresponding parts are denoted by the same reference numerals or symbols, and the description of such parts is omitted.

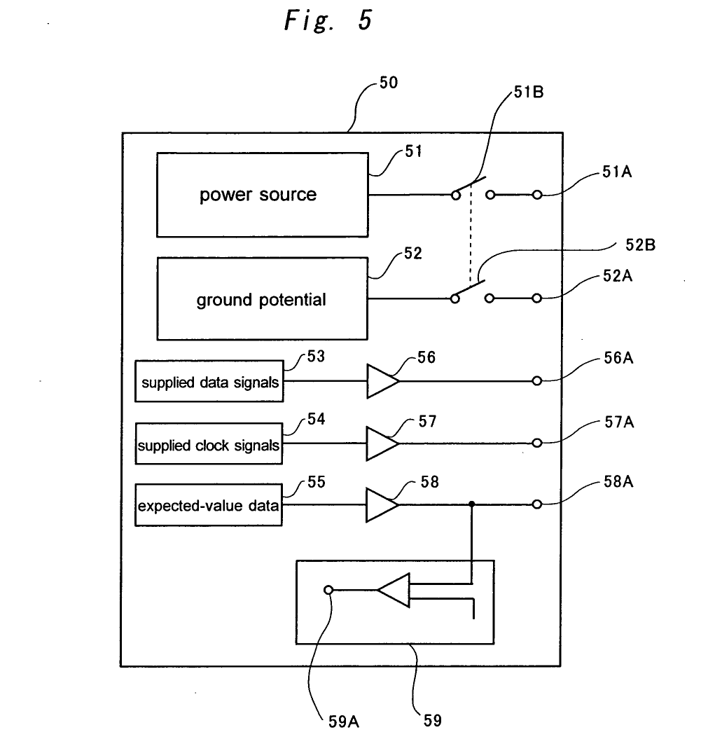

Furthermore, as FIG. 5 shows, relay contacts 51B and 52B may be provided on the output sides of the power source 51 for the device and the GND 52 for the device of the low-cost tester 50, respectively, and the controller (not shown) may be operated to release the relay contacts 51B and 52B when the handy comparator 59 outputs a signal of the defective DUT to isolate power source 51 for the device and the GND 52 for the device from the DUT.

### Fourth Embodiment

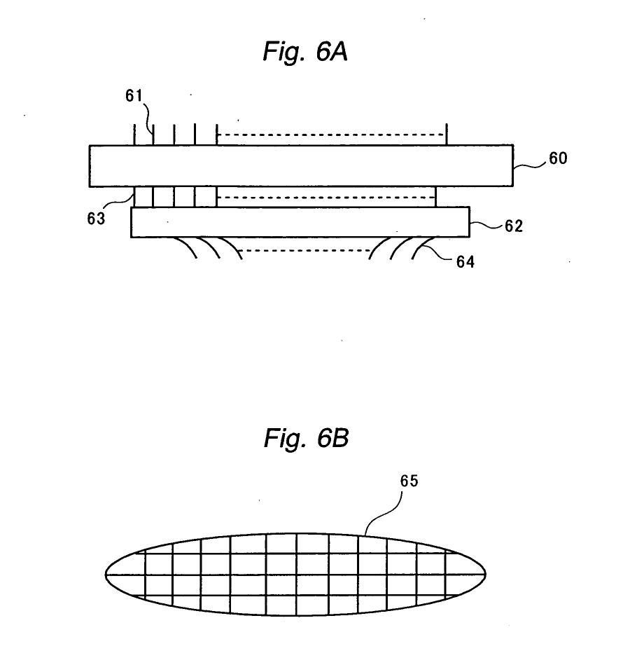

Next, Fourth Embodiment of the present invention will be described below referring to FIGS. 6A and 6B.

FIG. 6A and 6B are schematic diagrams showing the constitution of Fourth Embodiment, and showing a probing needle device for testing a DUT in a full-wafer manner.

FIG. 6A is a schematic diagram showing the constitution of the probing needle device, and FIG. 6B is a schematic diagram showing a wafer to be tested. In FIGS. 6A and 6B, the reference numeral 60 denotes a mother board, and 61 denotes POGO contacts disposed on the mother board 60, which receive signals from a handy tester (not shown) regardless of the type of the DUT.

The reference numeral 62 denotes a daughter board constituted by a multi-layer substrate, which constitutes the probing needle device together with the mother board 60, and different constitutions are used depending on the type of the DUT.

The reference numeral 63 denotes POGO contacts disposed on the daughter board 62, and 64 denotes needles also disposed on the daughter board 62, and scramblingly wired so as to have always the same condition with the POGO contacts, the number of which is five: a power source Vcc terminal, a GND terminal, a data supply terminal, a clock supply terminal, and a test result monitoring terminal (all not shown) for each device mounted on the wafer 65.

A conventional probing needle mechanism requires 100 or more needles for a device, and the price is 10 million yen or more, while in the probing needle device according to Fourth Embodiment, the number of required needles is dramatically reduced, and the price is also significantly lowered. The number of needles is not limited to five, but can be selected according to test items. For example, several needles may be used for one semiconductor device.

### Fifth Embodiment

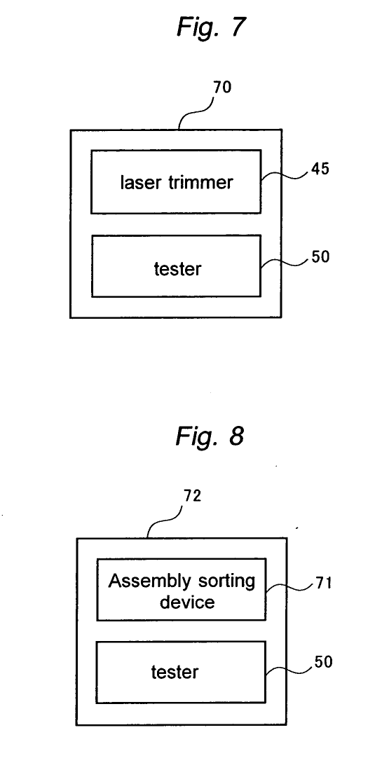

Next, Fifth Embodiment of the present invention will be described below referring to FIGS. 7 and 8.

FIG. 7 is a schematic diagram showing the constitution of Fifth Embodiment. In Fifth Embodiment, as FIG. 7 shows, a laser trimmer 45 and a low-cost tester 50 are integrated in a case 70, constitutions of which are described above, respectively.

Such a constitution not only allows a compact constitution, but also supplies the result of judgment correctly to the laser trimmer 45 when the comparator 59 of the low-cost tester 50 determines the quality of a DUT, and the reliability of memory operation can be improved. Also for the same purpose, in the test apparatus shown in FIG. 8, an assembly sorting device 71 for sorting DUT into good and defective one based on the output of the result of judgment, and the tester 50 are integrated in a case 72.

### Sixth Embodiment

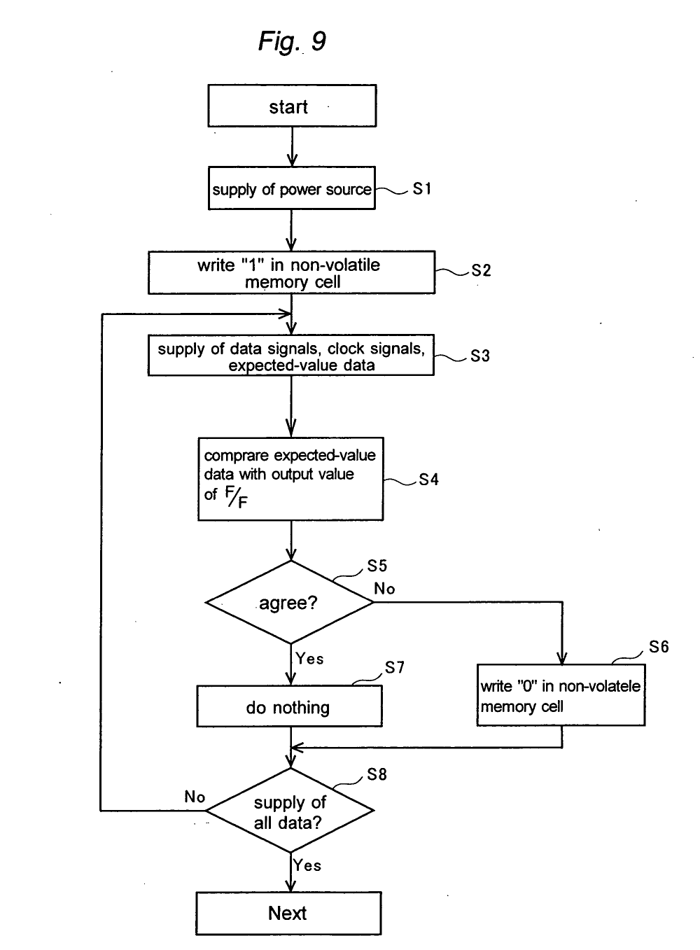

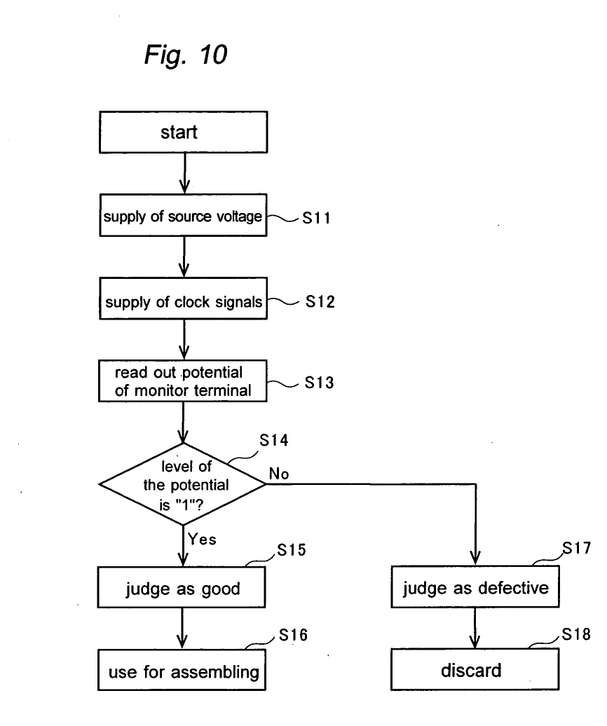

Next, Sixth Embodiment of the present invention will be described below referring to FIGS. 9 and 10.

FIG. 9 is a flow chart showing a test method according to Sixth Embodiment.

In Step S1, a power source Vcc and a ground potential GND are supplied to a DUT.

Next, in Step S2, “1” is written in advance in a non-volatile memory cell 33. In this case, however, an inverter 34 is not connected to the output side of the non-volatile memory cell 33 as shown in FIG. 1, and the output of the non-volatile memory cell 33 is outputted to the judgment output terminal 35 as it is.

Next, in Step S3, data signals, clock signals, and expected-value data are supplied to the DUT, and the test is conducted. Thereafter, in Step S4, the expected value is compared with the output value of F/F, which is the test result, in the device.

In Step S5, the agreement of the expected value and the test result is checked each time the clock signals are supplied. When they are agreed, nothing is done in the next Step S7, and when they are not agreed, “0” is written in the non-volatile memory cell in Step S6.

When the DUT has a fuse device, laser beams are radiated in the case of disagreement in Step S5 to melt the fuse and turn the output level to “0”. However, once the fuse is melted, this is memorized by raising a flag so as to prevent repeated melting. Next, in Step S8, supply of all data is checked. When all data is supplied, all the DUT on the wafer are tested in a full-wafer manner, and the following quality determination is performed.

FIG. 10 is a flow chart showing discrimination between good and defective DUT.

In Step S11, a source voltage is supplied; in Step S12, clock signals are supplied; and in Step S13, the potential of the monitor terminal, which is the output terminal of the non-volatile memory cell, is readout. Next, in Step S14, whether the level of the potential read out is “1” or not is checked. When the level of the potential is “1”, the DUT is judged as good in step S15, and is used for assembling in Step S16. If the level of the potential is not “1” in Step S14, the DUT is judged as defective, and is discarded in Step S18.

According to this flow chart, good and defective DUT can be discriminated very easily.

### Seventh Embodiment

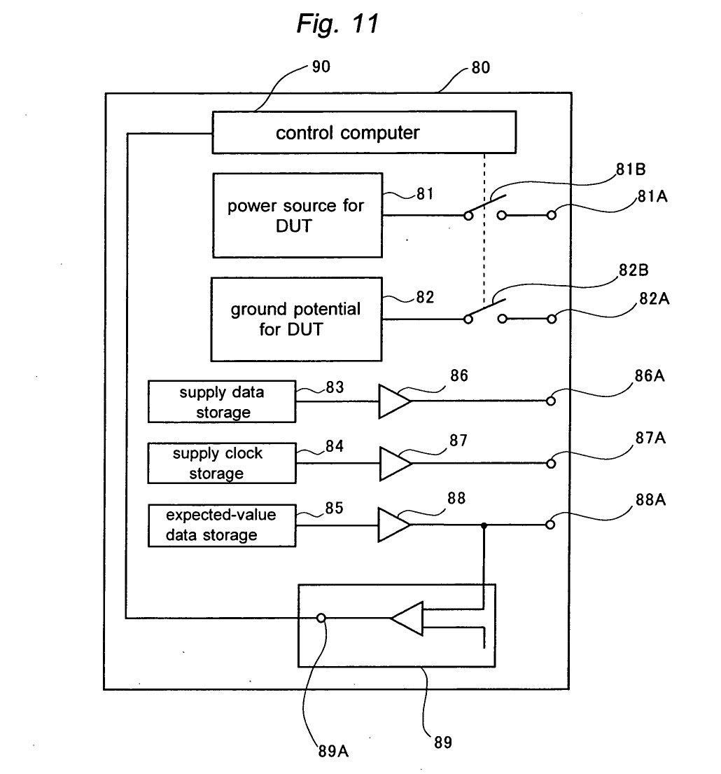

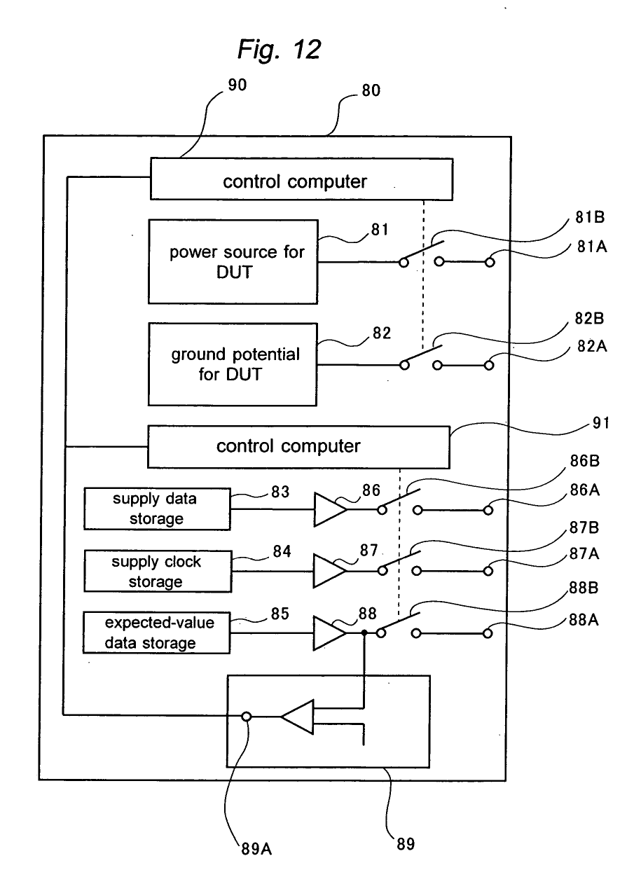

Next, Seventh Embodiment of the present invention will be described below referring to FIGS. 11 and 12.

FIG. 11 is a block diagram showing the constitution of Seventh Embodiment. In FIG. 11, the reference numeral 80 denotes a handy pin electronics card, which carries the components on a substrate, which components are described in the following description. The reference numeral 81 denotes a power source for the DUT, 81A denotes the supply terminal of the power source 81, 81B denotes a normally close relay contact disposed on the output side of the power source 81, 82 denotes a ground potential for the DUT, 82A denotes the supply terminal of the ground potential 82, 82B denotes a normally closed relay contact disposed on the output side of the ground potential 82, 83 denotes a supply data storage for storing data supplied to the DUT, 84 denotes a supply clock storage for storing clock signals supplied to the DUT, 85 denotes an expected-value data storage for storing expected-value data, 86 to 88 denote handy drivers to which supply data signals, supply clock signals, and expected-value data are inputted, respectively, and generate pulse signals corresponding to each of the signals, which are supplied to the data input terminal 20, the clock signal input terminal 22, and the expected-value data input terminal 24 shown in FIG. 1 through each of output terminals 86A to 88A, as in the above-described low-cost tester.

The reference numeral 89 denotes a handy comparator, which is the same as the comparator in the above-described low-cost tester. The reference numeral 90 denotes a control computer, which releases the relay contacts 81B and 82B of the power source 81 and the GND 82 when the output terminal 89A of the handy comparator 89 outputs the judgment of a defective DUT, to isolate the power source 81 and the GND 82 from the DUT.

In such a constitution, desired data are stored in the supply data storage 83, the supply clock storage 84, and the expected-value data storage 85, and the handy drivers 86 to 88 are controlled based on the data.

Although each of the supply data storage 83, the supply clock storage 84, and the expected-value data storage 85 is a special semiconductor device, these are very easy to manufacture when the present technology for manufacturing memory-incorporated logic large-scale integrated circuits, and three types of storages 83 to 85 can easily be implemented in one compact chip. The control computer 90 is a computer for electrically isolating the defective DUT, and may be substituted by a commercially available microcomputer.

FIG. 12 shows a constitution of the handy pin electronics card 80 shown in FIG. 11, to which a control computer 91 is added also to release the normally closed relay contacts 86B to 88B by the judgment signals from the handy comparator 89, and to isolate the output of handy drivers 86 to 88 from the DUT.

As a result, costs for the test can be reduced effectively.

### Eighth Embodiment

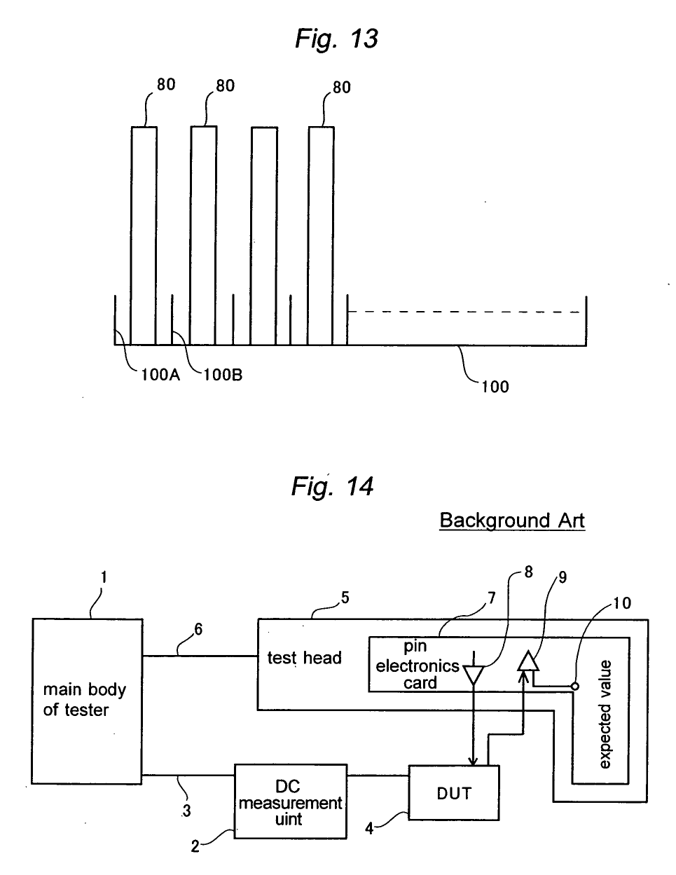

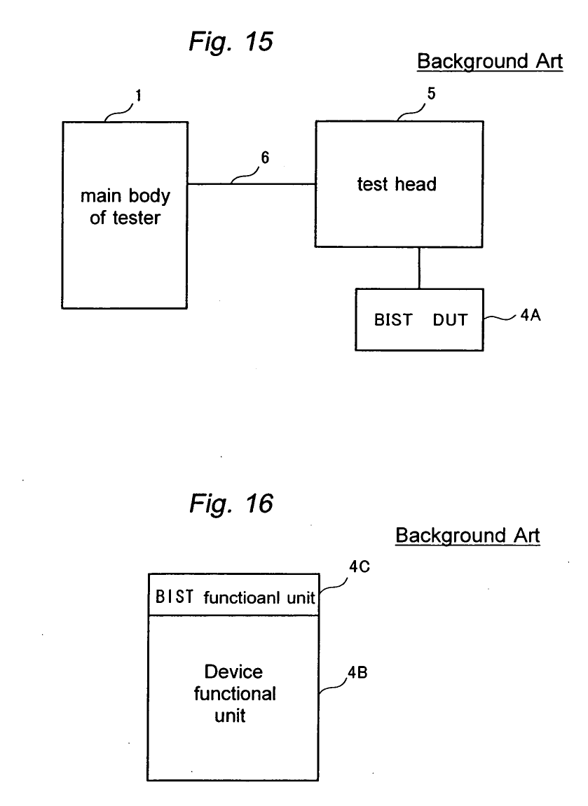

Next, Eighth Embodiment of the present invention will be described below referring to FIG. 13.

FIG. 13 is a schematic diagram showing the constitution and a testing method of Eighth Embodiment, and showing a low-cost tester for testing wafers carrying a plurality of DUT in a full-wafer manner at a time. In FIG. 13, the reference numeral 100 denotes a slot substrate in a low-cost tester, which has slots 10A, 10B, . . . of the same number as the DUT has carried (manufactured) on a wafer, and accommodates a handy pin electronics card 80 described in Seventh Embodiment in each slot.

Since each handy pin electronics card 80 incorporates control computers 90, 91 and storages 83 to 85, each handy pin electronics card 80 can operate independently; therefore, all the DUT can be tested at a time following the procedures of FIG. 9.

A test apparatus for semiconductor devices comprising:
a self-test circuit for test the semiconductor device and carried on the semiconductor device; a comparing and judging circuit for comparing the result of test with a expected-value data to judge the quality of the semiconductor device;
a non-volatile memory cell for storing the results of judgment on the semiconductor device; and a tester having drivers for supplying said semiconductor device with power source for the test, a ground potential, supply data signals, supply clock signals, and the expected-value data.

A test apparatus for semiconductor devices comprising:
a self-test circuit for test the semiconductor device and carried on the semiconductor device; a tester having:
   drivers for supplying the semiconductor device with power source for the test, a ground potential, supply data signals, supply clock signals, and expected-value data; and
   a comparing and judging circuit for comparing the result of test with the expected-value data to judge the quality of the semiconductor device;
a non-volatile memory cell carried on the semiconductor device and for storing the results of judgment.

The test apparatus for semiconductor devices, further comprising relay contacts connected to the power source for the semiconductor device and the circuit for supplying a ground potential; and a controller to open said relay contacts;
wherein when said comparing and judging circuit judges the semiconductor device to be defective, said controller operates to open said relay contacts.

A test apparatus for semiconductor devices comprising: a self-test circuit carried on the semiconductor device and for test the semiconductor device; a non-volatile memory cell for storing the results of judgment of the quality of the semiconductor device based on the result of test; a pin electronics card corresponding to the semiconductor device, said pin electronics card incorporating:
a power source and a ground potential supply source for the semiconductor device;
storages for storing data signals, clock signals, and expected-value data for said self-test circuit;
drivers for each of the signals connected to said each storage;
a comparator for comparing the result of the test obtained from the semiconductor device with the expected-value data, and for judging the quality of the semiconductor device; and
a controller for isolating the power source and ground potential from the semiconductor device when said comparator judges the semiconductor device to be defective.

The test apparatus for semiconductor devices, wherein said pin electronics card further incorporates a controller to isolate said comparator and said drivers for supply data signals, supply clock signals and expected-value data from the semiconductor device when said comparator judges the semiconductor device to be defective.

The test apparatus for semiconductor devices, further comprising a slot substrate that carries a plurality of pin electronics cards, wherein the semiconductor devices on a wafer are tested in a full-wafer manner by mounting pin electronics cards of the same number as the semiconductor devices on said slot substrate.

A method for testing semiconductor devices using the test apparatus, comprising the steps of: conducting the test using the self-test circuit by supplying a power source and a ground potential for the test, data signals and clock signals from the tester; comparing the result of the test with the expected value using the comparing and judging circuit in the semiconductor device or the tester to judge the quality; and storing the result of the judgment in the non-volatile memory cell of the selected good semiconductor device.

A method for testing semiconductor devices using the test apparatus, comprising the step of melting the fuse in the fuse device when the comparing and judging circuit judges the semiconductor device to be good, and thereafter outputting a judgment-result potential for the good semiconductor device.

A method for testing semiconductor devices using the test apparatus, comprising the steps of: writing data corresponding to the judgment output for good semiconductor devices previously in the non-volatile memory cell at the beginning of the test; and rewriting the data in the non-volatile memory cell only when the semiconductor device is judged to be defective by comparing the result of the test with the expected-value data.

A method for testing semiconductor devices using the test apparatus for semiconductor devices, comprising the steps of: supplying a potential corresponding to the judgment output for good semiconductor devices previously to the fuse device at the beginning of the test; changing the judgment output by melting the fuse in the fuse device only when the semiconductor device is judged to be defective by comparing the result of the test with the expected-value data.

This invention, when practiced illustratively in the manner described above, provides the following major effects:

The test apparatus can conduct tests efficiently and easily, can easily check the test results any time, and can reduce the costs for testing.

The test apparatus can easily check the test results, can conduct tests easily, and can reduce the costs for testing.

The test apparatus including the tester can be fabricated at a low cost, and the tests can be conducted easily.

The constitution of the probing needle device becomes simplified, and the price can be reduced significantly.

The size of the test apparatus can be reduced, the reliability of the test is improved, and the costs for testing can be lowered.

The test apparatus can be made to be a card type to reduce the size, and the costs for testing can be lowered. Also, all the DUT on a wafer can be tested in a full-wafer manner at a time.

The test is facilitated, and the costs for testing can further be lowered.

Further, the present invention is not limited to these embodiments, but variations and modifications may be made without departing from the scope of the present invention.

The entire disclosure of Japanese Patent Application No. 2001-211662 filed on Jul. 12, 2001 containing specification, claims, drawings and summary are incorporated herein by reference in its entirety.

1-11. (canceled)

12. A method of manufacturing semiconductor devices, comprising the steps of:
providing a semiconductor wafer having a plurality of semiconductor devices thereon, each semiconductor device having a self-test circuit and a comparing and judging circuit;
electrically connecting the semiconductor devices by supplying a power source, a ground potential, data signals, clock signals and expected value data to each of semiconductor devices from the test apparatus; and
judging quality of each of the semiconductor devices by comparing result of the test with the expected value data using the comparing and judging circuit thereof.

13. The method of manufacturing semiconductor devices according to claim 12,
wherein each of the semiconductor devices has a non-volatile memory cell for storing results of judgment, and
wherein the method further comprises a step of storing the results of judgment in the non-volatile memory cells of the semiconductor devices respectively.
